(19) United States
(12) Patent Application Publication
(10) Pub. No.: US 2006/0267146 A1
(43) Pub. Date: Nov. 30, 2006

(54) Multilayered emitter window for bipolar junction transistor

(75) Inventors: Noel Hoilien, Saint Paul, MN (US); Kyeonglan Rho, Maple Grove, MN (US); Daniel Fertig, Edina, MN (US); Steven Kosier, Lakeville, MN (US)

Correspondence Address: KINNEY & LANGE, P.A., THE KINNEY & LANGE BUILDING, 312 SOUTH THIRD STREET, MINNEAPOLIS, MN, 55415-1002, US

(73) Assignee: Polar Semiconductor, Inc., Bloomington, MN (US)

(21) Appl. No.: 11/436,390

(22) Filed: May 18, 2006

Related U.S. Application Data
(60) Provisional application No. 60/682,448, filed on May 19, 2005.

(51) Int. Cl. H01L 27/082; H01L 27/102

(52) U.S. Cl. 257/565

(57) ABSTRACT

An emitter window for a bipolar junction transistor includes a first emitter window layer adjacent to and in contact with a base region, a second emitter window layer adjacent to and in contact with the first layer and a third emitter window layer adjacent to and in contact with the second layer.

### CROSS-REFERENCE TO RELATED APPLICATION(S)

The present invention claims priority from U.S. Provisional Application No. 60/682,448, filed May 19, 2005 for “Silicon Dioxide and Silicon Nitride Layered Bipolar Junction Transistor for Intergration of a High Quality Anti-Reflective Coating into an Integrated Circuit Process” by N. Hoilien, K. Rho, D. Fertig and S. Kosier.

### INCORPORATION BY REFERENCE

The aforementioned Provisional Application No. 60/682,448 is hereby incorporated by reference in its entirety.

### BACKGROUND OF THE INVENTION

A bipolar junction transistor (BJT) is a three terminal device that can, when properly biased, controllably vary the magnitude of a current that flows between two of the terminals. The three terminals include a base terminal, a collector terminal and an emitter terminal. As its name implies, the BJT has two junctions of materials with different conductivity types. BJTs come in two types, NPN (negative-positive-negative) BJTs and PNP (positive-negative-positive) BJTs.

The BJT has three separately doped regions and two PN junctions, sufficiently close together so that interactions occur between the two junctions. In normal forward (or ‘on’) operation of an NPN transistor, for example, the base-emitter PN junction is forward biased and the base-collector PN junction is reverse biased. The base-emitter junction is forward biased so that electrons from the emitter are injected across the base-emitter junction into the base. These injected electrons create an excess concentration of minority carriers in the base. The base-collector junction is reverse biased so the minority carrier electron concentration at the edge of the base-collector junction is ideally zero. The large gradient in base electron concentration causes the electrons to diffuse across the base region into the base-collector space charge region, where the electric field will sweep the electrons into the collector.

A double polysilicon transistor is formed where both the emitter and base are made of polycrystalline silicon (polysilicon). In contrast, a single-polysilicon BJT is formed where only the emitter made of polysilicon. A double polysilicon transistor is said to be “self-aligned” when the distance between the polysilicon of the base and the polysilicon of the emitter is not defined by any photolithography operation.

A conventional method of fabricating a single polysilicon BJT begins with implanting base dopant into a semiconductor. Next, an insulating layer or layers, called the emitter window layers, are deposited over the base. An opening is etched into the emitter window layers. Both the opening in the emitter layers and the openings themselves are referred to collectively as the “emitter window”. Next, the emitter polysilicon is deposited. This emitter polysilicon contacts the underlying single-crystal silicon through the emitter window opening. The emitter polysilicon may be in-situ doped or implanted with dopant after the deposition. Subsequent high-temperature process steps diffuse some of the dopant from the emitter into the single-crystal silicon underneath the emitter window opening.

Transistors such as BJTs are commonly used in optical read systems. In order to improve the sensitivity of the optical read system, an anti-reflective coating (ARC) is used. The ARC allows the appropriate wavelengths of light to be transmitted through the coating with maximum transmission and minimum reflection. To minimize process complexity, ARCs are typically formed as one of the final steps in the manufacture of optical read integrated circuits. However, the presence of metal interconnects with a low melting point at the end of the process limits the ARC formation temperature and therefore limits the quality of the ARC. To achieve a high quality ARC, it must be formed before metal interconnect. However, if the ARC is formed before metal interconnect, either additional process steps must be added to remove the ARC from all devices except those that specifically require the ARC (such as photodiodes) or the ARC layers must be incorporated into devices that do not specifically require the ARC (such as BJTs).

Thus, there is a need in the art for BJTs that can be fabricated in conjunction with an anti-reflective coating for use in optical systems. There is also a need in the art for BJTs that have accurate endpoint detection when etching the emitter window.

### BRIEF SUMMARY OF THE INVENTION

The invention is a multi-layered emitter window used in a single polysilicon bipolar junction transistor. A bipolar junction transistor including the multi-layered emitter window allows application of a high-quality anti-reflective coating to an integrated circuit to be incorporated into the fabrication process and also provides improved endpoint detection during etching of the emitter window.

### BRIEF DESCRIPTION OF THE DRAWINGS

FIG. 1 is a cross-sectional view of a single polysilicon BJT including an emitter window according to one embodiment of the invention.

FIG. 2A is a cross-section view of a single polysilicon BJT emitter window as known in the prior art.

FIG. 2B is a cross-section view of a double polysilicon BJT with an emitter window as known in the prior art.

While the above-identified figures set forth embodiments of the invention, other embodiments are also contemplated, as noted in the discussion. In all cases, this disclosure presents the invention by way of representation, and not limitation. It should be understood that numerous other modifications and embodiments that fall within the scope and spirit of the principles of this invention can be devised by those skilled in the art. The figures may not be drawn to scale.

### DETAILED DESCRIPTION

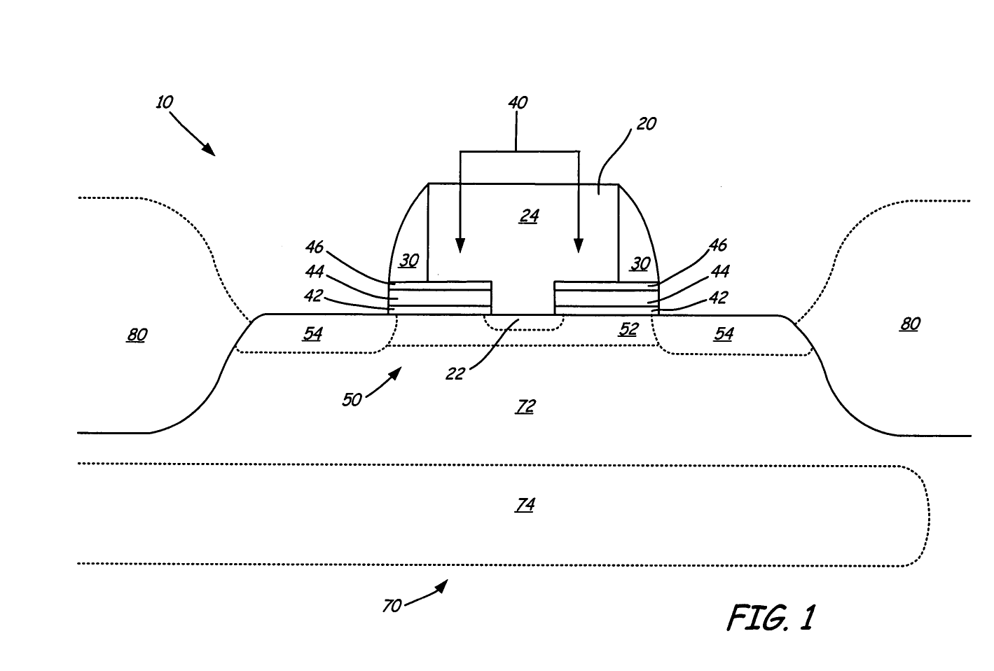

FIG. 1 shows an implementation of the present invention. BJT 10 includes emitter 20, which consists of out-diffused emitter dopant 22 and emitter polysilicon 24. Spacer 30 is located on both sides of emitter polysilicon 24 and is typically composed of silicon oxide. However, other materials may also be used. Emitter polysilicon 24 contacts out-diffused emitter dopant 22 through an opening in emitter window 40. Emitter window 40 includes layers 42, 44 and 46. Typically, layer 42 is made of silicon oxide, layer 44 is made of silicon nitride, and layer 46 is made of an oxide. However, other materials may also be used.

Base 50 of BJT 10 consists of base implant 52 and heavily-doped base contact 54. Heavily-doped base contact 54 is separated from out-diffused emitter dopant 22 by base implant 52. During fabrication, spacer 30 is used to separate heavily-doped base contact 54 from out-diffused emitter dopant 22. Collector 70 of BJT 10 includes lightly-doped epitaxial layer 72 and heavily-doped buried layer 74. BJT 10 is isolated from neighboring devices by field oxide 80.

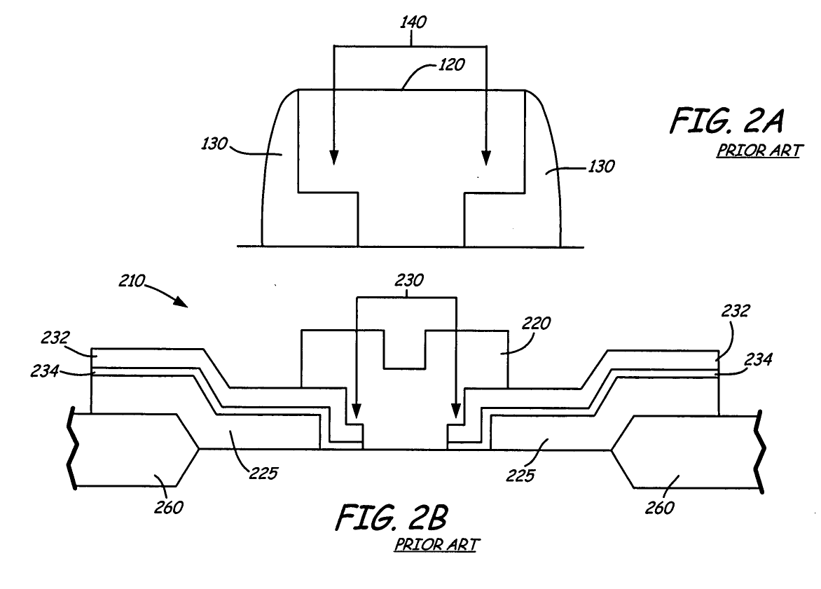

FIG. 2 shows the prior art for purposes of comparison. FIG. 2A shows emitter polysilicon 120 bounded on either side by oxide spacer 130. Emitter polysilicon 120 contacts the underlying single-crystal through an opening in emitter window 140.

FIG. 2B shows double-polysilicon bipolar junction transistor 210 with emitter 220 and base 225. Emitter 220 and base 225 are separated by double layered emitter window 230, which includes oxide layer 232 and nitride layer 234.

The invention demonstrates improved end-point detection during etching of the emitter window. After deposition of the emitter window layers 42, 44 and 46, the layers must be etched. This is not unique to the invention. Even if a single layered emitter window is used, the single layer must be etched to create an opening. However, when etching the emitter window layer or layers, it is desirable to remove as much of the emitter window layers as possible in the desired location, without etching away any of the silicon beneath it. Thus, it is important to be able to accurately detect the end-point of the emitter window etch so that additional material, such as the base, is not etched away. At the same time, it is not desirable to stop etching too soon, since this will leave emitter window material in places on the circuit where it is not wanted.

The multi-layered emitter window of the invention improves etch end-point detection. When etching the surface of an integrated circuit, the material being etched away can be detected by sensors. If a single material is used for the emitter window layer (silicon oxide, for instance), then the etched material will all be silicon oxide. Sensing that silicon oxide is being removed will not be helpful until all of the oxide is etched away, and the underlying silicon is being removed. However, if a multi-layered emitter window material is used, then different materials will be detected as the etch progresses. For example, if the emitter window is made of oxide-nitride-oxide layers, then the first material etched away will be oxide. When all the top layer oxide is gone, the nitride will be detected as being removed, so it will be known that the second layer is now being etched. Similarly, it can be detected when the nitride etch is complete and the bottom layer of oxide is being removed. At this point, it will be known that that the final layer of emitter window material is being removed. In this way, it is much easier to estimate when all of the emitter window material has been removed and the underlying silicon has been reached.

Another advantage of the invention is that it is easy to integrate application of anti-reflective coatings to integrated circuits utilizing the invention. Photodiodes and other optical applications benefit from anti-reflective coatings that maximize the signal by reducing losses of light from reflection. Use of a dual layer anti-reflective coating instead of a single layer anti-reflective coating can further reduce reflection or loss. Using silicon nitride as a second layer of a double layer anti-reflective coating has the additional benefit of protecting the photodiode from humidity and contaminants.

In building emitter window 40, layer 42 is first grown by thermal oxidation or deposited. Next, layer 44 is deposited on top of layer 42, and layer 46 is deposited on layer 44. Portions of layers 42, 44 and 46 are etched away to form emitter window 40. However, layers 42 and 44 form a dual-layer anti-reflective coating. Thus, deposition of these layers serves the dual purpose of creating multi-layered emitter window 40 and creating a high quality anti-reflective coating over the other areas of the integrated circuit.

The invention is a multi-layered emitter window in a single-polysilicon BJT. The multi-layered emitter window exhibits improved end-point detection during etching, and it is easily incorporated into integrated circuit fabrication that includes application of an anti-reflective coating.

Although the present invention has been described with reference to preferred embodiments, workers skilled in the art will recognize that changes may be made in form and detail without departing from the spirit and scope of the invention.

1. An emitter window for a bipolar junction transistor comprising:
a first emitter window layer adjacent to and in contact with a base region and an emitter;
a second emitter window layer adjacent to and in contact with the first layer and the emitter and
a third emitter window layer adjacent to and in contact with the second layer and the emitter.

2. The emitter window of claim 1 wherein the first emitter window layer is comprised of an insulator.

3. The emitter window of claim 2 wherein the first emitter window layer is comprised of silicon oxide.

4. The emitter window of claim 1 wherein the second emitter window layer is comprised of an insulator.

5. The emitter window of claim 4 wherein the second emitter window layer is comprised of silicon nitride.

6. The emitter window of claim 1 wherein the third emitter window layer is comprised of an insulator.

7. The emitter window of claim 6 wherein the third emitter window layer is comprised of silicon oxide.

8. The emitter window of claim 1 further comprising a multi-layer anti-reflective coating integral with the emitter window layers.

9. A semiconductor device comprising:
a base region of a first conductivity type;
an emitter region of a second conductivity type;
a collector region of a second conductivity type; and
an emitter window formed of first, second and third emitter window layers.

10. The semiconductor device of claim 9 wherein the first emitter window layer is comprised of an insulator.

11. The semiconductor device of claim 10 wherein the first emitter window layer is comprised of silicon oxide.

12. The semiconductor device of claim 9 wherein the second emitter window layer is comprised of an insulator.

13. The semiconductor device of claim 12 wherein the second emitter window layer is comprised of silicon nitride.

14. The semiconductor device of claim 9 wherein the third emitter window layer is comprised of an insulator.

15. The semiconductor device of claim 14 wherein the third emitter window layer is comprised of silicon oxide.

16. The semiconductor device of claim 9 further comprising a multi-layer anti-reflective coating integral with the emitter window layers.

17. A method for fabricating bipolar junction transistors, the method comprising:
implanting a base region on a semiconductor body;
depositing a first emitter window layer on the base region;
depositing a second emitter window layer on the first emitter window layer;
depositing a third emitter window layer on the second emitter window layer;
etching the first, second and third emitter window layers to form an emitter window; and
depositing a polysilicon emitter region in the emitter window.

18. The semiconductor device of claim 17 wherein the first emitter window layer is comprised of an insulator.

19. The semiconductor device of claim 18 wherein the first emitter window layer is comprised of silicon oxide.

20. The semiconductor device of claim 17 wherein the second emitter window layer is comprised of an insulator.

21. The semiconductor device of claim 20 wherein the second emitter window layer is comprised of silicon nitride.

22. The semiconductor device of claim 17 wherein the third emitter window layer is comprised of an insulator.

23. The semiconductor device of claim 22 wherein the third emitter window layer is comprised of silicon oxide.
